(19) United States
(12) Patent Application Publication
(10) Pub. No.: US 2014/0253206 A1
(43) Pub. Date: Sep. 11, 2014

(54) SYSTEMS AND METHODS FOR PROVIDING LOW-PASS FILTERING

(71) Applicant: QUALCOMM INCORPORATED, San Diego, CA (US)

(72) Inventors: Yi Tang, San Diego, CA (US); Bo Sun, Carlsbad, CA (US)

(73) Assignee: QUALCOMM INCORPORATED, San Diego, CA (US)

(21) Appl. No.: 13/794,066

(22) Filed: Mar. 11, 2013

(51) Int. Cl. H03H 11/04

(52) U.S. Cl. CPC H03H 11/0405
USPC 327/311

(57) ABSTRACT

A low-pass filter circuit is described. The low-pass filter circuit includes a pseudo-resistor. The pseudo-resistor includes at least one metal-oxide-semiconductor field-effect transistor. The at least one metal-oxide-semiconductor field-effect transistor receives a digital power supply domain signal. The low-pass filter circuit also includes a capacitor. The capacitor is coupled to the pseudo-resistor. The capacitor provides a filtered signal. The low-pass filter circuit may pass digital signal transitions and provide low-pass filtering when there is no signal transition.

### TECHNICAL FIELD

The present disclosure relates generally to electronic systems. More specifically, the present disclosure relates to systems and methods for providing low-pass filtering.

### BACKGROUND

In the last several decades, the use of electronic devices has become common. In particular, advances in electronic technology have reduced the cost of increasingly complex and useful electronic devices. Cost reduction and consumer demand have proliferated the use of electronic devices such that they are practically ubiquitous in modern society.

As the use of electronic devices has expanded, so has the demand for new and improved features of electronic devices. More specifically, electronic devices that perform functions faster, more efficiently or with higher quality are often sought after. Reduced size of an electronic device or its circuitry may also be a factor. However, producing electronic devices with these improved capabilities and/or performance in reduced size may be difficult.

For example, many electronic devices incorporate circuits that include both digital circuitry and analog circuitry. In some cases, noise from digital circuitry can degrade analog circuitry performance. As can be seen from this discussion, systems and methods for reducing noise may be beneficial.

### SUMMARY

A low-pass filter circuit is described. The low-pass filter circuit includes a pseudo-resistor including at least one metal-oxide-semiconductor field-effect transistor that receives a digital power supply domain signal. The low-pass filter also includes a capacitor coupled to the pseudo-resistor. The capacitor provides a filtered signal. The low-pass filter circuit may pass digital signal transitions and provide low-pass filtering when there is no signal transition.

The at least one metal-oxide-semiconductor field-effect transistor may be an n-channel metal-oxide-semiconductor field-effect transistor and/or a p-channel metal-oxide-semiconductor field-effect transistor. The at least one metal-oxide-semiconductor field-effect transistor may have its transistor gate coupled to its transistor drain and may have its transistor body coupled to its transistor source.

The low-pass filter circuit may attenuate noise in the digital power supply domain signal to provide the filtered signal. The low-pass filter circuit may be a first order low-pass filter.

The pseudo-resistor may be coupled to a first circuitry in a digital power supply domain. The first circuitry may include a digital inverter that receives a digital input signal and provides a digital power supply domain signal. The first circuitry may be coupled to a digital power supply that provides power to the first circuitry.

The pseudo-resistor and the capacitor may be coupled to a second circuitry. The second circuitry may include an inverter that receives the filtered signal and provides an analog power supply domain signal. The second circuitry may be coupled to an analog power supply that provides power to the inverter.

The pseudo-resistor may provide low resistance when the digital power supply domain signal is in transition. The pseudo-resistor may provide high resistance when the digital power supply domain signal is not in transition.

The pseudo-resistor may include a p-channel metal-oxide-semiconductor field-effect transistor and an n-channel metal-oxide-semiconductor field-effect transistor. A source of the p-channel metal-oxide-semiconductor field-effect transistor may be coupled to a source of the n-channel metal-oxide-semiconductor field-effect transistor, a drain of the p-channel metal-oxide-semiconductor field-effect transistor may be coupled to a drain of the n-channel metal-oxide-semiconductor field-effect transistor, a gate of the p-channel metal-oxide-semiconductor field-effect transistor may be coupled the drain of the p-channel metal-oxide-semiconductor field-effect transistor, and a gate of the n-channel metal-oxide-semiconductor field-effect transistor may be coupled to the drain of the n-channel metal-oxide-semiconductor field-effect transistor.

The pseudo-resistor may include a p-channel metal-oxide-semiconductor field-effect transistor. A source of the p-channel metal-oxide-semiconductor field-effect transistor receives the digital power supply domain signal and a drain of the p-channel metal-oxide-semiconductor field-effect transistor may be coupled to the capacitor.

The pseudo-resistor may include an n-channel metal-oxide-semiconductor field-effect transistor. A source of the n-channel metal-oxide-semiconductor field-effect transistor may receive the digital power supply domain signal and a drain of the n-channel metal-oxide-semiconductor field-effect transistor may be coupled to the capacitor.

A method for providing low-pass filtering is also described. The method includes receiving a digital power supply domain signal by a pseudo-resistor. The pseudo-resistor includes at least one metal-oxide-semiconductor field-effect transistor. The method also includes filtering the digital power supply domain signal. The method further includes providing a filtered signal by a capacitor. The capacitor is coupled to the pseudo-resistor.

A computer-program product for providing low-pass filtering is also described. The computer-program product includes a non-transitory tangible computer-readable medium with instructions. The instructions include code for causing a pseudo-resistor to receive a digital power supply domain signal. The pseudo-resistor includes at least one metal-oxide-semiconductor field-effect transistor. The instructions also include code for causing a capacitor to provide a filtered signal. The capacitor is coupled to the pseudo-resistor.

An apparatus for providing low-pass filtering is also described. The apparatus includes means for providing a resistance that receives a digital power supply domain signal. The means for providing the resistance does not include a passive element. The apparatus also includes means for providing a capacitance. The means for providing the capacitance is coupled to the means for providing the resistance. The means for providing the capacitance provides a filtered signal.

### BRIEF DESCRIPTION OF THE DRAWINGS

FIG. 1 is a block diagram illustrating one configuration of a low-pass filter circuit in which systems and methods for providing low-pass filtering may be implemented;

FIG. 2 is a block diagram illustrating a more specific configuration of a low-pass filter circuit in which systems and methods for providing low-pass filtering may be implemented;

FIG. 3 is a flow diagram illustrating one configuration of a method for providing low-pass filtering;

FIG. 4 is a flow diagram illustrating a more detailed configuration of a method for providing low-pass filtering;

FIG. 5 is a circuit diagram illustrating a more specific configuration of a low-pass filter circuit in which systems and methods for providing low-pass filtering may be implemented;

FIG. 6 is a circuit diagram illustrating another more specific configuration of a low-pass filter circuit in which systems and methods for providing low-pass filtering may be implemented;

FIG. 7 is a circuit diagram illustrating another more specific configuration of a low-pass filter circuit in which systems and methods for providing low-pass filtering may be implemented;

FIG. 8 includes various graphs illustrating circuit transfer functions;

FIG. 9 includes various graphs illustrating various examples of signals and circuit transfer functions;

FIG. 10 illustrates various components that may be utilized in an electronic device; and

FIG. 11 illustrates certain components that may be included within a wireless communication device.

### DETAILED DESCRIPTION

It should be noted that an ordinal term (e.g., “first,” “second,” “third,” etc.) may not by itself indicate any priority or number of elements with respect to another, but may distinguish the one element from another element. Unless expressly limited by its context, each of the terms “plurality” and “set” is used herein to indicate an integer quantity that is greater than one.

Systems-on-chip (SoC) have been employed in a variety of consumer electronics devices such as smart phones, wireless modems, tablet devices, gaming systems, etc. For example, a SoC offers a small footprint and low cost solution by integrating analog circuits with digital circuits. To interact with the external analog world with high fidelity, noise-prone analog input signals such as voltage, current, charge and radio waves generally need to be amplified, filtered and frequency translated before they are digitized to more robust and often rail-to-rail digital switching signals. In such implementations, digital power supply noise coupling from a digital switching system to a sensitive analog side is one of the major sources of noise that degrades analog circuit performance. For example, digital power supply noise may interfere with a digital control signal for a digitally-controlled oscillator (DCO). In another example, digital power supply noise may interfere with a digital interface signal for data converters and switching power amplifiers (PAs).

In some implementations, a large bypass capacitance may be placed near a power supply. The bypass capacitance may provide low impedance at high frequency such that the switching noise may be attenuated. This may require a large silicon area for an on-chip bypass capacitor or an explicit power supply pin for off-chip capacitor implementation. In these implementations, the layout may need to be carefully designed to establish good isolation between the analog side and the digital side of an integrated circuit.

Some implementations of the systems and methods described herein may include a very simple architecture with a miniature metal-oxide-semiconductor field-effect transistor (MOSFET) pair. This architecture may achieve a 20 decibel attenuation of the noise at a very low cutoff frequency. More specifically, the systems and methods disclosed herein may relate to using pseudo-resistors to implement a low-pass filter at the last stage of a digital circuit such that the power supply noise from the digital switching circuits would be attenuated by 20 decibels across an interface between the analog circuits and the digital circuits.

With the transistor gate coupled to the drain (terminal) and the body coupled to the source, a miniature p-channel metal-oxide-semiconductor field-effect transistor (PMOS transistor) and n-channel metal-oxide-semiconductor field-effect transistor (NMOS transistor) pair (coupled as described below, for example) may generate a very large resistance (e.g., in the gigaohm range) when the voltage across the drain of the MOSFETs and the source of the MOSFETs is small. A PMOS transistor and NMOS transistor pair may be connected in serial to a small capacitor (e.g., in the femtoFarad range) to act as a first-order low-pass filter with a very low cut-off frequency to filter out the power supply noise.

During the switching instances, the voltage across the pseudo-resistor drain and source may be large enough to turn on the MOSFETs as diode-connected MOSFETs or bipolar junction transistors (BJTs) with small resistance. In these implementations, a high-speed digital signal may propagate to the analog side, where it may be recovered to full swing with a simple inverter.

In some configurations, the pseudo-resistor low-pass filter may include an NMOS transistor and a PMOS transistor or equivalent structure and a shunt capacitor at the output. This pseudo-resistor low-pass filter may be inserted into a digital signal line connecting digital and analog signal buffers. The digital and analog signal buffers at the input and output of the pseudo-resistor low-pass filter may be connected to different power supply domains.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods. Features and/or elements depicted in a Figure may be combined with one or more features and/or elements depicted in one or more other Figures.

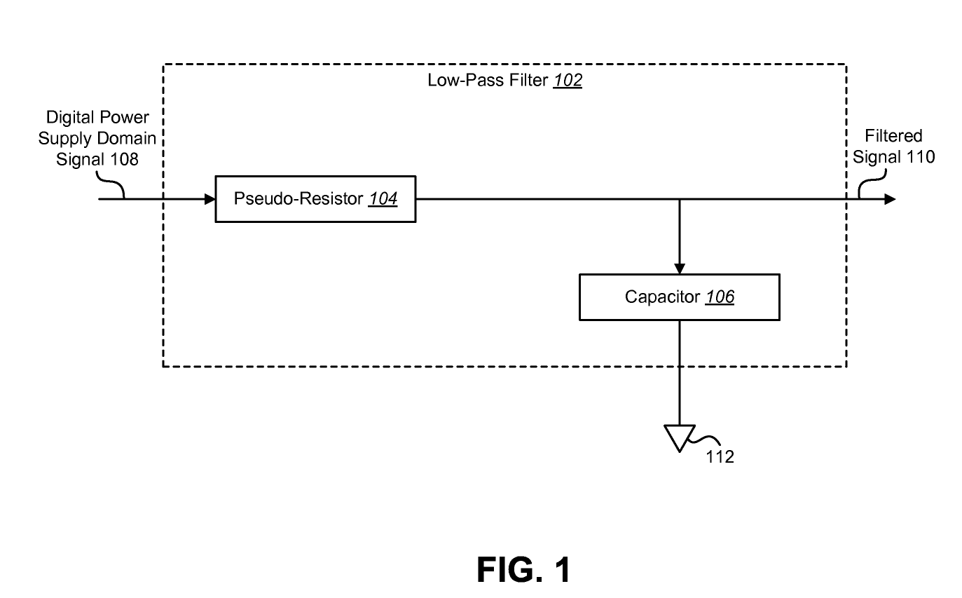

FIG. 1 is a block diagram illustrating one configuration of a low-pass filter circuit 102 in which systems and methods for providing low-pass filtering may be implemented. The low-pass filter circuit 102 may be an electronic circuit (e.g., an integrated circuit) that filters a digital power supply domain signal 108.

As illustrated, the low-pass filter circuit 102 may be a first-order low-pass filter circuit 102. For example, the pseudo-resistor 104 and the capacitor 106 may be coupled as illustrated to provide a first-order low-pass filter circuit 102. In other implementations, the low-pass filter circuit 102 may be a higher order low-pass filter (e.g., a second order low-pass filter). The low-pass filter circuit 102 may provide a low cut-off frequency.

The low-pass filter circuit 102 may include a pseudo-resistor 104 and a capacitor 106. The pseudo-resistor 104 may provide or generate resistance in the low-pass filter circuit 102. The pseudo-resistor 104 may include one or more active elements (e.g., transistors, MOSFETs). In some configurations, the pseudo-resistor 104 may not include a passive element (e.g., passive resistor). Accordingly, the pseudo-resistor 104 may provide a resistance without a passive element in some configurations.

The pseudo-resistor 104 may include one or more MOSFETs. In one configuration, the pseudo-resistor 104 may include a single NMOS transistor. In another configuration, the pseudo-resistor 104 may include a single PMOS transistor. In yet other configurations, the pseudo-resistor 104 may include a plurality of MOSFETs. For example, the pseudo-resistor 104 may include an NMOS transistor and a PMOS transistor. In this example, the NMOS transistor and a PMOS transistor may be coupled together in parallel. This may provide a high resistance when the voltage across the drains of the transistors and the sources of the transistors is small. For instance, the resistance resulting from coupling an NMOS transistor and a PMOS transistor may be in the 10-gigaohm range. In some configurations, at least one transistor included in the pseudo-resistor may have its transistor gate coupled to its transistor drain (terminal) and its transistor body coupled to its transistor source (terminal).

The capacitor 106 may be coupled to the pseudo-resistor 104. The capacitor 106 may also be coupled to ground 112. In some configurations, the capacitor 106 may be coupled to analog ground for better noise isolation (in implementations where both analog ground and digital ground are provided, for example). The capacitor 106 may be a shunt capacitor. It should be noted that the capacitor 106 may be an actual capacitor and not a parasitic capacitance.

The capacitor 106 may be a small capacitor and/or may exhibit low capacitance (in the femtofarad range, for example). More specifically, the capacitor 106 can be relatively small because the pseudo-resistor 104 provides a large resistance. Accordingly, the low-pass filter circuit 102 may be implemented in a small area on an integrated circuit while providing filtering with a low cut-off frequency.

The digital power supply domain signal 108 may be produced in a digital power supply domain. For example, a digital power supply may power circuitry that generates the digital power supply domain signal 108. The low-pass filter circuit 102 may attenuate noise (e.g., switching noise) in the digital power supply domain signal 108 (originating from a digital power supply and/or circuitry in the digital power supply domain, for instance).

The pseudo-resistor 104 may receive the digital power supply domain signal 108. When the digital power supply domain signal 108 is in transition, the pseudo-resistor 104 may exhibit low resistance. As used herein, a “low resistance” is lower than a “high resistance.” In some configurations, a “transition” may be a change in the logical state of a signal (e.g., from a logical zero state to a logical one state or from a logical one state to a logical zero state). Accordingly, the systems and methods disclosed herein (e.g., the low-pass filter circuit 102) may pass digital signal transitions and provide low-pass filtering when there is no signal change (e.g., transition).

More specifically, when the voltage difference across the pseudo-resistor 104 is large (e.g., the voltage difference between the source and drain of a MOSFET is large), the pseudo-resistor 104 may exhibit low resistance. Accordingly, the low-pass filter circuit 102 may pass transitions with larger voltage differences (e.g., logic transitions) with small attenuation. However, when the voltage difference across the pseudo-resistor 104 is small (e.g., the voltage difference between the source and drain of a MOSFET is small), the pseudo-resistor 104 may exhibit high resistance. Accordingly, when the digital power supply domain signal 108 is not in transition (e.g., constant logical state), the pseudo-resistor 104 may exhibit high resistance. Thus, the low-pass filter circuit 102 may filter more noise when the digital power supply domain signal 108 is not in transition while passing transitions in the digital power supply domain signal 108 (with less attenuation, for example).

The capacitor 106 may provide a filtered signal 110 (e.g., the digital power supply domain signal 108 with attenuated noise). The filtered signal 110 may be a digital control signal with attenuated digital power supply noise.

In some configurations, the low-pass filter circuit 102 may couple (e.g., interface) a digital power supply domain to an analog power supply domain. For example, the low-pass filter circuit 102 may be inserted or coupled between the last stage of circuitry in a digital supply domain and the first stage of circuitry in an analog power supply domain. For instance, the low-pass filter circuit 102 may be coupled to an inverter in the digital power supply domain and/or to an inverter in the analog power supply domain. The low-pass filter circuit 102 may provide the filtered signal 110 (e.g., a noise attenuated digital control signal) to circuitry in the analog power supply domain, such as a digital-to-analog converter (DAC), an analog-to-digital converter (ADC), a phase locked-loop (PLL) and/or a synthesizer.

In some implementations, the low-pass filter circuit 102 may be located on an integrated circuit. The integrated circuit may be located on an electronic device. For example, the low-pass filter circuit 102 may be located on an integrated circuit of an electronic device such as a mobile communication device (e.g., a smartphone).

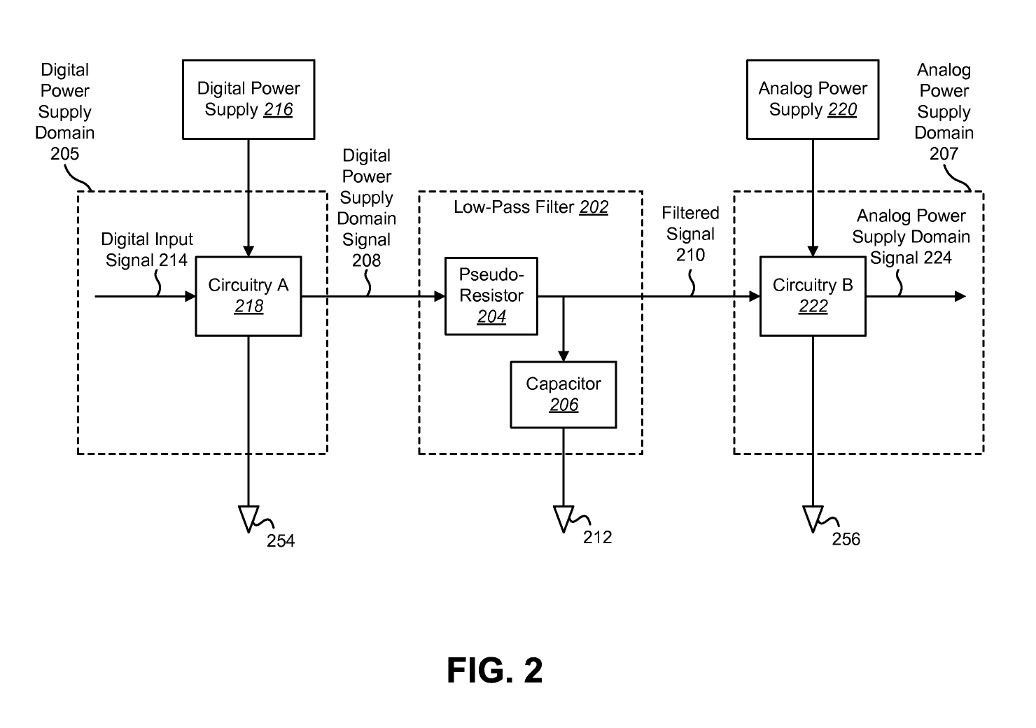

FIG. 2 is a block diagram illustrating a more specific configuration of a low-pass filter circuit 202 in which systems and methods for providing low-pass filtering may be implemented. The low-pass filter circuit 202 may be an example of the low-pass filter circuit 102 described in connection with FIG. 1. The low-pass filter circuit 202 may include a pseudo-resistor 204 and a capacitor 206 that may be examples of corresponding elements described in connection with FIG. 1. For example, the capacitor 206 may be coupled to ground 212 as described in connection with FIG. 1.

In this configuration, the low-pass filter circuit 202 is coupled between a digital power supply domain 205 and an analog power supply domain 207. The digital power supply domain 205 may include one or more circuitries that are powered by a digital power supply 216. For example, the digital power supply domain 205 may include circuitry A 218. Accordingly, the digital power supply 216 is coupled to and provides electrical power to (e.g., applies a supply voltage to) circuitry A 218. Circuitry A 218 may be coupled to digital ground 254.

Circuitry A 218 may receive a digital input signal 214. For example, circuitry A 218 may receive a digital input signal 214 (e.g., a binary signal) from one or more other digital circuitries. In some implementations, the digital input signal 214 may be a digital control signal. For example, the digital input signal 214 may be a digital control signal for controlling one or more analog components of an electronic device (e.g., circuitry in the analog power supply domain 207).

Circuitry A 218 may process the digital input signal 214 to produce a digital power supply domain signal 208. For example, circuitry A 218 may include a digital inverter or buffer (among other elements, for instance). The digital power supply 216 and/or circuitry A 218 may produce noise in the digital power supply domain signal 208 as described above. Circuitry A 218 may provide the digital power supply domain signal 208 to the low-pass filter circuit 202 (e.g., to the pseudo-resistor 204).

Circuitry A 218 (e.g., the last stage of the digital power supply domain 205) may be coupled to the low-pass filter circuit 202 (e.g., the pseudo-resistor 204). The low-pass filter circuit 202 may attenuate or filter out the power supply noise from the digital power supply domain signal 208 to produce the filtered signal 210 as described above in connection with FIG. 1.

The low-pass filter circuit 202 (e.g., the pseudo-resistor 204 and the capacitor 206) may be coupled to the analog power supply domain 207. The analog power supply domain 207 may include one or more circuitries that are powered by an analog power supply 220. For example, the analog power supply domain 207 may include circuitry B 222. Accordingly, the analog power supply 220 is coupled to and provides electrical power to (e.g., applies a supply voltage to) circuitry B 222. Circuitry B 222 may be coupled to analog ground 256. In some configurations, the analog power supply domain 207 may include one or more of a digital-to-analog converter, an analog-to-digital converter, a phase locked-loop and a synthesizer.

Circuitry B 222 may be coupled to the low-pass filter circuit 202 (e.g., the pseudo-resistor 204 and the capacitor 206). Circuitry B 222 may receive the filtered signal 210 from the low-pass filter circuit 202. As described above, the filtered signal 210 may be a version of the digital power supply domain signal 208 with attenuated noise (e.g., power supply noise).

Circuitry B 222 may process the filtered signal 210 to produce an analog power supply domain signal 224. For example, circuitry B 222 may include an inverter or a buffer (among other elements, for example). The analog power supply domain signal 224 may be utilized in a variety of applications depending on the configuration. It should be noted that circuitry B 222 (e.g., an inverter or buffer) may still be a digital circuit in some configurations, though circuitry B 222 may work in the analog power supply domain 207. Furthermore, the analog power supply domain signal 224 may be a digital control signal for analog circuits, for example. It should be noted that one or more of the components (e.g., digital power supply 216, circuitry A 218, other circuit(s) in the digital power supply domain 205, low-pass filter circuit 202, circuitry B 222, analog power supply 220, other circuit(s) in the analog power supply domain 207) and/or elements thereof described in connection with FIG. 2 may be implemented on the same circuit and/or separate circuits.

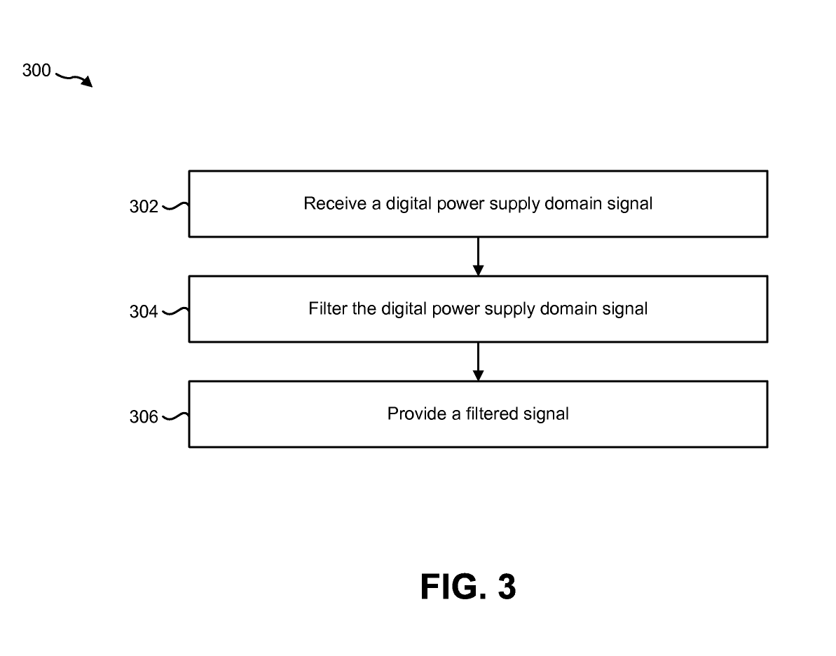

FIG. 3 is a flow diagram illustrating one configuration of a method 300 for providing low-pass filtering. The low-pass filter circuit 102 (e.g., pseudo-resistor 104) may receive 302 a digital power supply domain signal 108. For example, the pseudo-resistor 104 (e.g., the source of at least one MOSFET) may receive 302 a digital power supply domain signal 108 from circuitry A 218. One example of a digital power supply domain signal 108 is a digital control signal that switches between a high logic voltage level (e.g., “1”) and a low logic voltage level (e.g., “0”).

The low-pass filter circuit 102 may filter 304 the digital power supply domain signal 108. Filtering 304 the digital power supply domain signal 108 may produce a filtered signal 110. For example, the low-pass filter circuit 102 may attenuate noise in the digital power supply domain signal 108 to produce a filtered signal 110 as described above.

The low-pass filter circuit 102 (e.g., the capacitor 106) may provide 306 a filtered signal 110. For example, the capacitor 106 may provide 306 the filtered signal 110 to circuitry B 222. Circuitry B 222 may process the filtered signal 110 to produce an analog power supply domain signal 224 in some configurations.

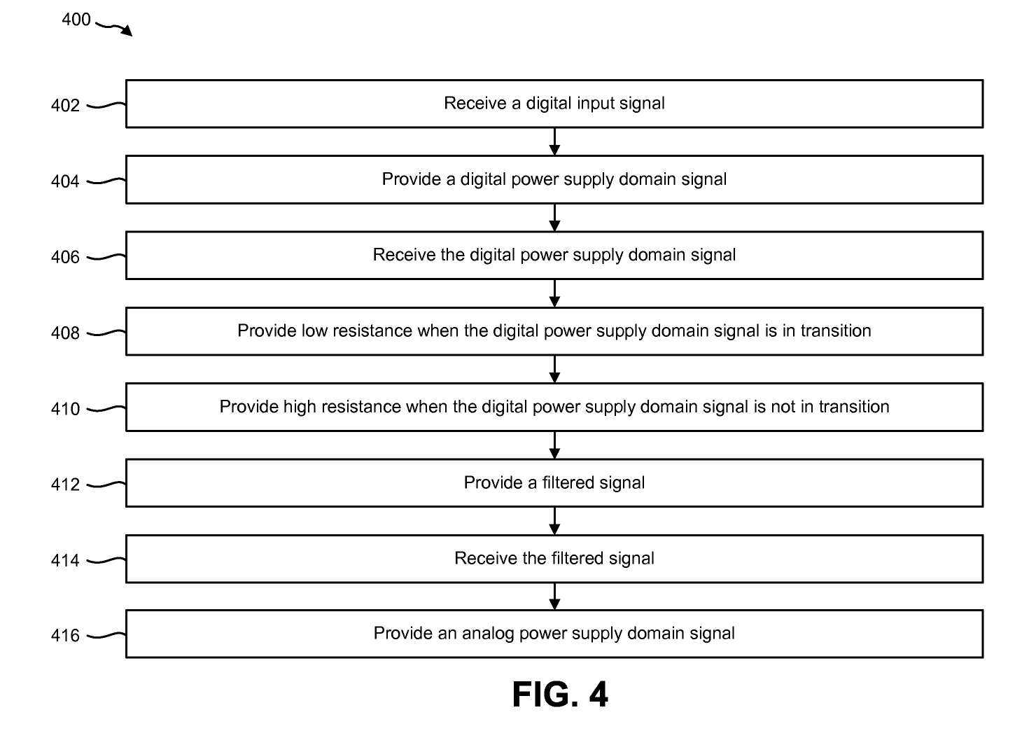

FIG. 4 is a flow diagram illustrating a more detailed configuration of a method 400 for providing low-pass filtering. Circuitry A 218 (in a digital power supply domain 205) may receive 402 a digital input signal 214. For example, circuitry A 218 may receive 402 a digital input signal 214 from the one or more other digital circuitries. The digital power supply 216 may provide power to circuitry A 218.

Circuitry A 218 may provide 404 a digital power supply domain signal 208 (based on the digital input signal, for example). For instance, circuitry A 218 may process the digital input signal to produce the digital power supply domain signal 208, which is provided 404 to the low-pass filter circuit 202 (e.g., the pseudo-resistor 204). In one configuration, circuitry A 218 is an inverter, which inverts the digital input signal to produce the digital power supply domain signal 208. Noise produced by the digital power supply 216 and/or circuitry A 218 may be injected into the digital power supply domain signal 208 as described above.

The low-pass filter circuit 202 (e.g., the pseudo-resistor 204) may receive 406 the digital power supply domain signal 208. In some configurations, this may be done as described in connection with FIG. 3.

The pseudo-resistor 204 may provide 408 low resistance when the digital power supply domain signal 208 is in transition (e.g., a logical state transition). For example, a transition of the digital power supply domain signal 208 may occur when the voltage difference across the pseudo-resistor 204 is large. More specifically, a digital power supply domain signal 208 may be in transition when the voltage difference between the source and the drain of a MOSFET is large (e.g., large enough to activate or turn on the MOSFET as a diode-connected MOSFET or BJT).

The pseudo-resistor 204 may provide 410 high resistance when the digital power supply domain signal 208 is not in transition (e.g., steady-state). For example, a digital power supply domain signal 208 may not be in a transition state when the voltage difference across the pseudo-resistor 204 is small. More specifically, a digital power supply domain signal 208 may not be in transition when the voltage difference between the source and the drain of a MOSFET is small (e.g., too small to activate or turn on the MOSFET). Providing 408 low resistance in transition and providing 410 high resistance in steady-state may enable low-pass filtering as described above.

The low-pass filter circuit 202 (e.g., the capacitor 206) may provide 412 a filtered signal 210. For example, the filtered signal 210 may be provided 412 at the coupling of the pseudo-resistor 204 and the capacitor 206. In some implementations, this may be done as described in connection with FIG. 3.

Circuitry B 222 may receive 414 a filtered signal 210. For example, circuitry B 222 may receive 414 a filtered version of the digital power supply domain signal 208 (with attenuated power supply noise) from the low-pass filter circuit 202.

Circuitry B 222 may provide 416 an analog power supply domain signal 224. The analog power supply domain signal 224 may be based on the filtered signal 210. For example, circuitry B 222 may be an inverter or buffer that processes the filtered signal 210 to generate the analog power supply domain signal 224 as described above. Circuitry B 222 may accordingly provide 416 the analog power supply domain signal 224 to one or more circuitries (e.g., analog circuitries). The analog power supply 220 may provide power to circuitry B 222.

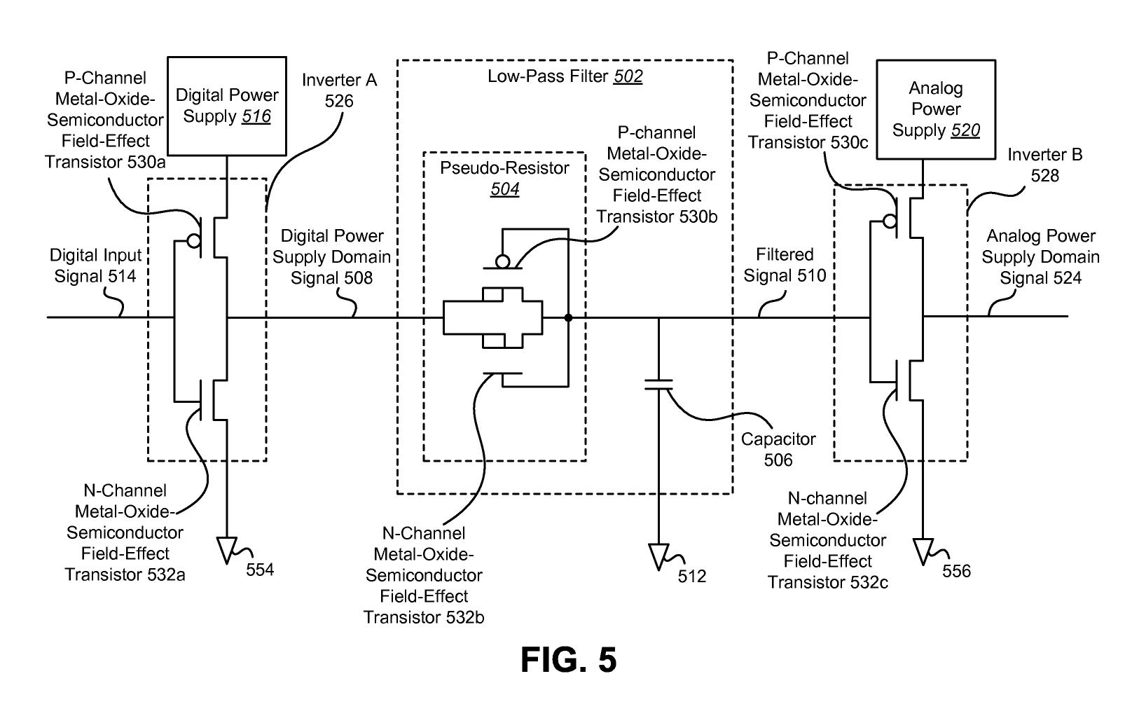

FIG. 5 is a circuit diagram illustrating a more specific configuration of a low-pass filter circuit 502 in which systems and methods for providing low-pass filtering may be implemented. The low-pass filter circuit 502 may be an example of the low-pass filter circuit 102 described in connection with FIG. 1. The low-pass filter circuit 502 includes a pseudo-resistor 504 and a capacitor 506 that may be examples of corresponding elements described in connection with FIG. 1.

In the configuration illustrated in FIG. 5, the pseudo-resistor 504 includes a PMOS transistor 530b coupled to an NMOS transistor 532b. The source of the PMOS transistor 530b is coupled to the source of the NMOS transistor 532b. Furthermore, the drain of the PMOS transistor 530b is coupled to the drain of the NMOS transistor 532b. The drain of the PMOS transistor 530b is further coupled to the gate of the PMOS transistor 530b. Additionally, the drain of the NMOS transistor 532b is coupled to the gate of the NMOS transistor 532b. For example, the PMOS transistor 530b and the NMOS transistor 532b may be diode-connected MOSFETs. Additionally or alternatively, one or more of the PMOS transistor 530b and the NMOS transistor 532b may have its respective transistor gate coupled to its transistor drain and may have its respective transistor body coupled to its transistor source.

The sources of the NMOS transistor 532b and the PMOS transistor 530b may receive the digital power supply domain signal 508 that may be an example of the digital power supply domain signal 108 described in connection with FIG. 1. The drains of the NMOS transistor 532b and the PMOS transistor 530b are coupled to a capacitor 506. The capacitor 506 may be coupled to ground 512 (e.g., analog ground). The capacitor 506 may provide the filtered signal 510 that may be an example of the filtered signal 110 described in connection with FIG. 1.

In the configuration illustrated in FIG. 5, the low-pass filter 502 may be coupled to inverter A 526 (e.g., a digital inverter). Inverter A 526 may be an example of circuitry A 218 (in the digital power supply domain 205) described in connection with FIG. 2. In this configuration, inverter A 526 includes a PMOS transistor 530a and an NMOS transistor 532a. The gate of the PMOS transistor 530a is coupled to the gate of the NMOS transistor 532a. In this configuration, the gates of the PMOS transistor 530a and the NMOS transistor 532a receive the digital input signal 514 (from one or more other digital circuitries, for example). The source of the PMOS transistor 530a is coupled to the digital power supply 516. The drain of the PMOS transistor 530a is coupled to the drain of the NMOS transistor 532a. Furthermore, the source of the NMOS transistor 532a is coupled to digital ground 554.

Inverter A 526 provides a digital power supply domain signal 508 that may be an example of the digital power supply domain signal 108 described in connection with FIG. 1. The digital power supply domain signal 508 may be based on the digital input signal 514 that may be an example of the digital input signal 214 described in connection with FIG. 2.

The low-pass filter 502 is coupled to inverter B 528 (e.g., a digital inverter). Inverter B 528 may be an example of circuitry B 222 described in connection with FIG. 2. In this configuration, inverter B 528 includes a PMOS transistor 530c and an NMOS transistor 532c. The gate of the PMOS transistor 530c is coupled to the gate of the NMOS transistor 532c. In particular, the gate of the PMOS transistor 530c and the NMOS transistor 532c receive the filtered signal 510. The source of the PMOS transistor 530c may be coupled to the analog power supply 520. The drain of the PMOS transistor 530c may be coupled to the drain of the NMOS transistor 532c. The source of the NMOS transistor 532c may be coupled to analog ground 556.

Inverter B 528 provides an analog power supply domain signal 524 that may be an example of the analog power supply domain signal 224 described in connection with FIG. 2. For example, inverter B 528 may provide the analog power supply domain signal to one or more other analog circuitries.

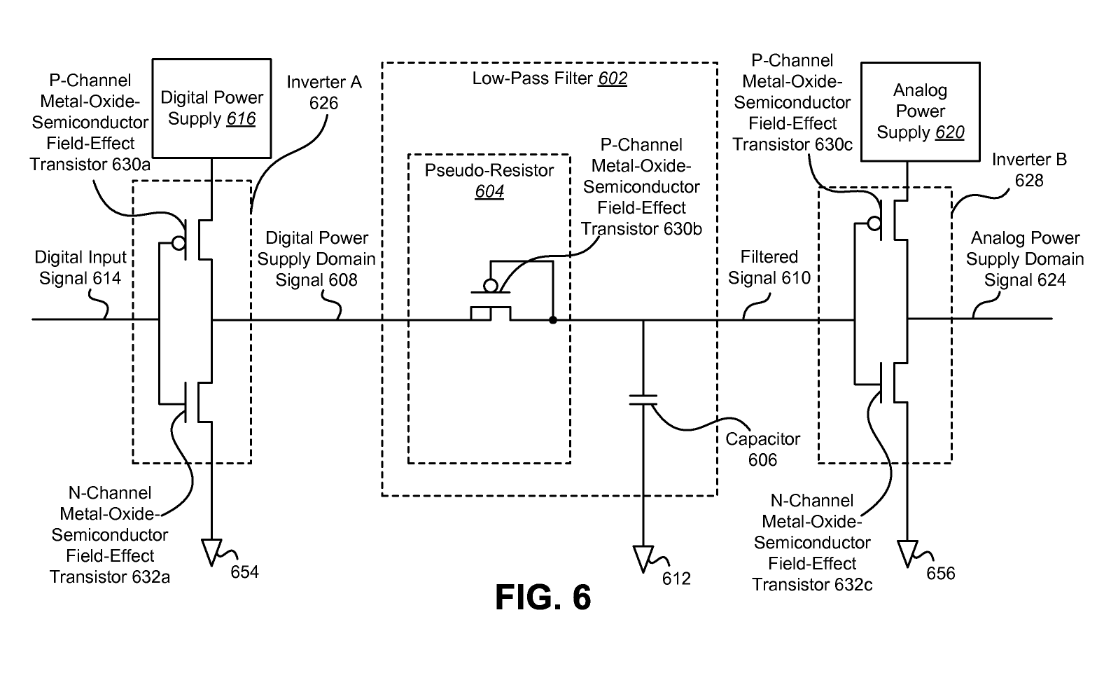

FIG. 6 is a circuit diagram illustrating another more specific configuration of a low-pass filter circuit 602 in which systems and methods for providing low-pass filtering may be implemented. The low-pass filter circuit 602 may be an example of the low-pass filter circuit 102 described in connection with FIG. 1. The low-pass filter circuit 602 illustrated in FIG. 6 includes a pseudo-resistor 604 and a capacitor 606 that may be examples of corresponding elements described in connection with FIG. 1.

In the configuration illustrated in FIG. 6, the pseudo-resistor 604 includes a PMOS transistor 630b. The source of the PMOS transistor 630b receives the digital power supply domain signal 608 that may be an example of the digital power supply domain signal 108 described in connection with FIG. 1. The drain of the PMOS transistor 630b is coupled to the capacitor 606. The capacitor 606 may be coupled to ground 612 (e.g., analog ground). The capacitor 606 provides the filtered signal 610 that may be an example of the filtered signal 110 described in connection with FIG. 1. The gate of the PMOS transistor 630b is coupled to the drain of the PMOS transistor 630b (e.g., the PMOS transistor 630b may be diode-connected). Additionally or alternatively, the PMOS transistor 630b may have its transistor gate coupled to its transistor drain and may have its transistor body coupled to its transistor source.

The digital power supply 616, inverter A 626 (including a PMOS transistor 630a and an NMOS transistor 632a that is coupled to digital ground 654), the analog power supply 620, inverter B 628 (including a PMOS transistor 630c and an NMOS transistor 632c that is coupled to analog ground 656) may be configured in accordance with corresponding elements described above in connection with FIG. 5. Furthermore, the digital input signal 614, digital power supply domain signal 608, filtered signal 610 and/or analog power supply domain signal 624 may be examples of corresponding signals described above in connection with FIG. 5.

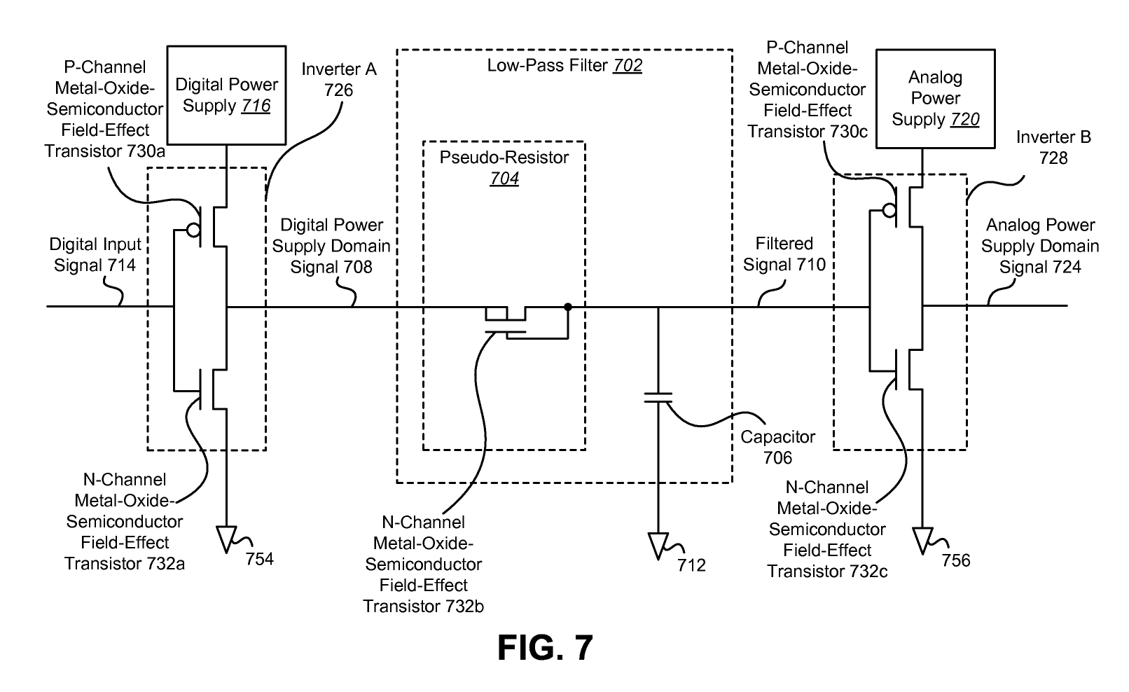

FIG. 7 is a circuit diagram illustrating another more specific configuration of a low-pass filter circuit 702 in which systems and methods for providing low-pass filtering may be implemented. The low-pass filter circuit 702 may be an example of the low-pass filter circuit 102 described in connection with FIG. 1. The low-pass filter circuit 702 illustrated in FIG. 7 includes a pseudo-resistor 704 and a capacitor 706 that may be examples of corresponding elements described in connection with FIG. 1.

In the configuration illustrated in FIG. 7, the pseudo-resistor 704 includes an NMOS transistor 732b. The source of the NMOS transistor 732b receives the digital power supply domain signal 708 that may be an example of the digital power supply domain signal 108 described in connection with FIG. 1. The drain of the NMOS transistor 732b is coupled to the capacitor 706. The capacitor 706 may be coupled to ground 712 (e.g., analog ground). The capacitor 706 provides the filtered signal 710 that may be an example of the filtered signal 110 described in connection with FIG. 1. The gate of the NMOS transistor 732b is coupled to the drain of the NMOS transistor 732b (e.g., the NMOS transistor 732b may be diode-connected). Additionally or alternatively, the NMOS transistor 732b may have its transistor gate coupled to its transistor drain and may have its transistor body coupled to its transistor source.

The digital power supply 716, inverter A 726 (including a PMOS transistor 730a and an NMOS transistor 732a that is coupled to digital ground 754), the analog power supply 720, inverter B 728 (including a PMOS transistor 730c and an NMOS transistor 732c that is coupled to analog ground 756) may be configured in accordance with corresponding elements described above in connection with FIG. 5. Furthermore, the digital input signal 714, digital power supply domain signal 708, filtered signal 710 and/or analog power supply domain signal 724 may be examples of corresponding signals described above in connection with FIG. 5.

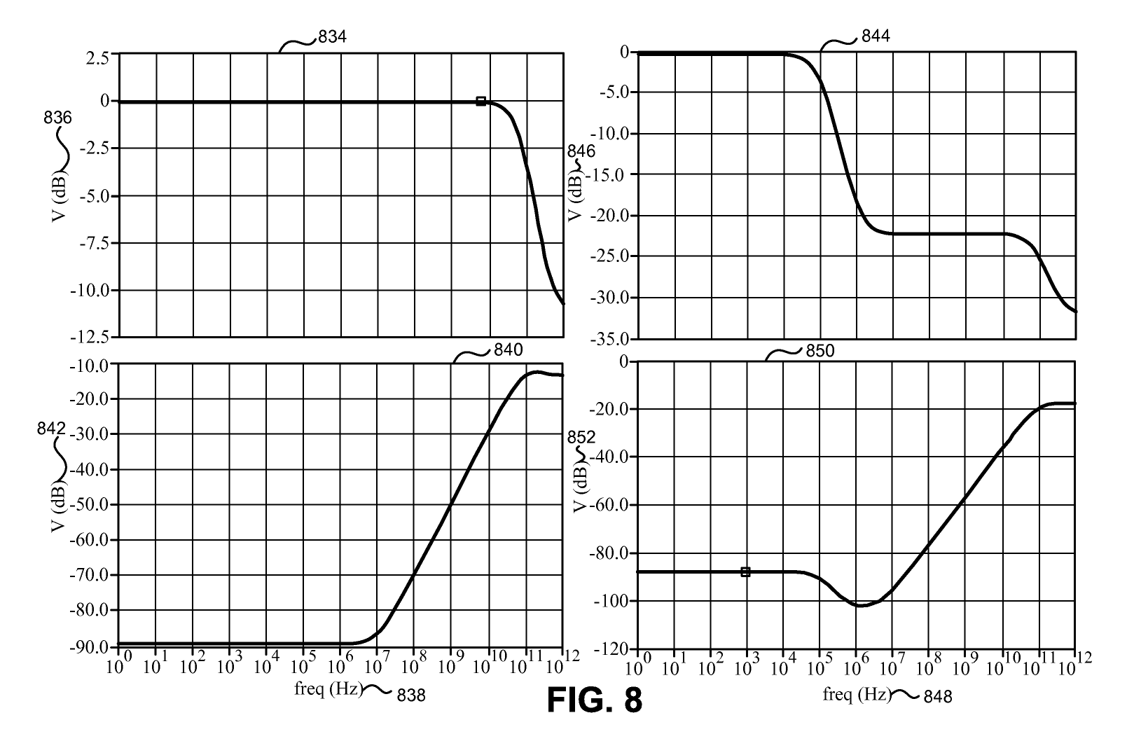

FIG. 8 includes various graphs 834, 840, 844, 850 illustrating circuit transfer functions. In particular, the graphs 834, 840, 844, 850 may illustrate the transfer functions at various circuit nodes.

The first graph 834 (top left) and the second graph 840 (bottom left) illustrate transfer functions (e.g., responses) of a circuit without a low-pass filter circuit 102 as described above. The y-axes 836, 842 of the first graph 834 and second graph 840 are given in volts in decibels (dBs). The x-axis 838 of the first graph 834 and second graph 840 is given in frequency in hertz (Hz).

The first graph 834 illustrates the transfer function from a digital power supply to an analog supply domain input (without the low-pass filter circuit 102). As illustrated, the circuit behaves as a low-pass filter up to approximately 10 gigahertz. The second graph 840 illustrates the transfer function from a digital power supply to the output of an inverter in the analog power supply domain (without the low-pass filter circuit 102). As illustrated, the output may be attenuated by approximately 10 decibels at approximately 100 gigahertz. In other words, the minimum attenuation from zero hertz to approximately one terahertz is approximately 10 decibels.

By comparison, the third graph 844 (upper right) and the fourth graph 850 (lower right) illustrate the transfer functions of a circuit that includes an example of the low-pass filter circuit 102 in accordance with the systems and methods disclosed herein. The y-axes 846, 852 of the third graph 844 and fourth graph 850 are given in volts in decibels (dBs). The x-axis 848 of the third graph 844 and fourth graph 850 is given in frequency in hertz (Hz).

The third graph 844 illustrates the transfer function of a circuit from the digital power supply 216 output to the low-pass filter circuit 102 output. As illustrated, there may be a low-pass corner at approximately 10 kilohertz. As frequency increases from that point, the response attenuates signals by approximately 22 decibels. Another low-pass corner may exist at approximately 10 gigahertz. The response attenuates signals further from that point with increasing frequency. The fourth graph 850 illustrates the transfer function from the digital power supply 216 output to the output of an inverter in the analog power supply domain 207 (e.g., circuitry B 222). The analog power supply domain signal 224 may be attenuated by a minimum of approximately 20 decibels (up to approximately 100 gigahertz as illustrated. For example, from 0 hertz to approximately 1 terahertz, the analog power supply domain signal 224 may include noise that is attenuated by approximately 20 decibels at least.

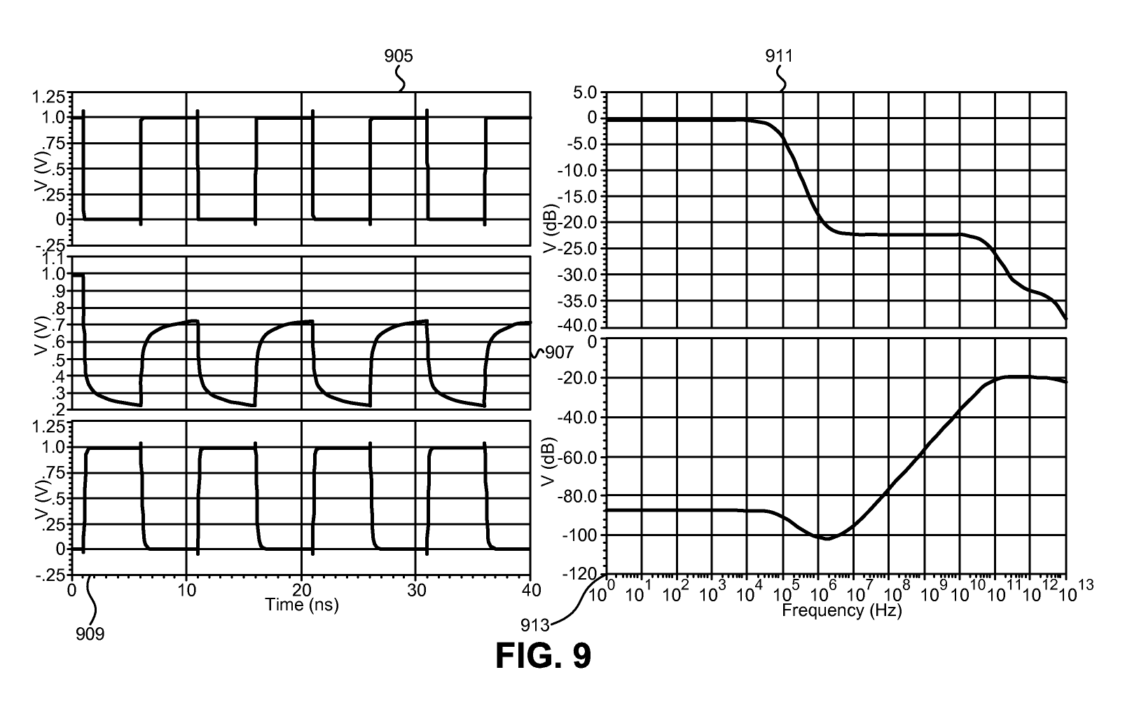

FIG. 9 includes various graphs 905, 907, 909, 911, 913 illustrating various examples of signals and circuit transfer functions. The first graph 905 (top left) illustrates one example of a digital power supply domain signal 208 (at the output of the digital power supply domain 205 and/or the input to the low-pass filter circuit 202). In particular, the first graph 905 illustrates transients of a digital power supply domain signal 208. The vertical axis of the first graph 905 illustrates voltage in volts, while the horizontal axis of the first graph 905 illustrates time in nanoseconds (ns).

The second graph 907 (middle left) illustrates one example of a filtered signal 210 (at the output of the low-pass filter circuit 202 and/or the input to the analog power supply domain 207). In particular, the second graph 907 illustrates a filtered signal 210 at the output of the low-pass filter circuit 202 corresponding to the digital power supply domain signal 208 illustrated in the first graph 905. As illustrated in the second graph 907, the signal is slightly attenuated while the transitions in the digital power supply domain signal 208 are maintained. The vertical axis of the second graph 907 illustrates voltage in volts, while the horizontal axis of the second graph 907 illustrates time in nanoseconds (ns).

The third graph 909 (bottom left) illustrates one example of an analog power supply domain signal 224 (at the output of circuitry B 222 (e.g., an inverter)). In particular, the third graph 909 illustrates an analog power supply domain signal 224 at the output of circuitry B 222 corresponding to the digital power supply domain signal 208 illustrated in the first graph 905 and corresponding to the filtered signal 210 illustrated in the second graph 907. As illustrated in the third graph 909, the transitions in the digital power supply domain signal 208 are maintained while filtering is provided by the low-pass filter circuit 202. The vertical axis of the third graph 909 illustrates voltage in volts, while the horizontal axis of the third graph 909 illustrates time in nanoseconds (ns).

The fourth graph 911 (upper right) and the fifth graph 913 (lower right) illustrate the transfer functions of a circuit that includes an example of the low-pass filter circuit 202 in accordance with the systems and methods disclosed herein. The vertical axes of the fourth graph 911 and fifth graph 913 illustrate voltage in decibels (dBs). The horizontal axis of the fourth graph 911 and fifth graph 913 illustrates frequency in hertz (Hz).

The fourth graph 911 illustrates the transfer function of a circuit from the digital power supply 216 output to the low-pass filter circuit 202 output. As illustrated, there may be a low-pass corner at approximately 10 kilohertz. As frequency increases from that point, the response attenuates signals by approximately 22 decibels. Another low-pass corner may exist at approximately 10 gigahertz. The response attenuates signals further from that point with increasing frequency. The fifth graph 913 illustrates the transfer function from the digital power supply 216 output to the output of circuitry B 222 (e.g., an inverter) in the analog power supply domain 207. The analog power supply domain signal 224 may be attenuated by a minimum of approximately 20 decibels (up to approximately 100 gigahertz as illustrated. For example, from 0 hertz to approximately 1 terahertz, the analog power supply domain signal 224 may include noise that is attenuated by approximately 20 decibels at least.

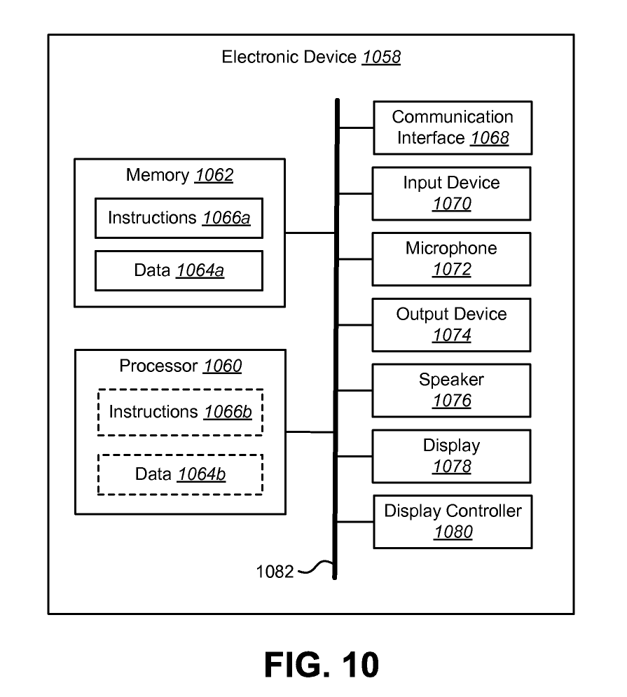

FIG. 10 illustrates various components that may be utilized in an electronic device 1058. The illustrated components may be located within the same physical structure or in separate housings or structures. In some configurations, one or more of the low-pass filter circuits 102, 202, 502, 602, 702 and/or other circuitries or elements described herein may be implemented in accordance with (e.g., included within) the electronic device 1058 illustrated in FIG. 10. The electronic device 1058 includes a processor 1060. The processor 1060 may be a general purpose single- or multi-chip microprocessor (e.g., an ARM), a special purpose microprocessor (e.g., a digital signal processor (DSP)), a microcontroller, a programmable gate array, etc. The processor 1060 may be referred to as a central processing unit (CPU). Although just a single processor 1060 is shown in the electronic device 1058 of FIG. 10, in an alternative configuration, a combination of processors 1060 (e.g., an ARM and DSP) could be used.

The electronic device 1058 also includes memory 1062 in electronic communication with the processor 1060. That is, the processor 1060 can read information from and/or write information to the memory 1062. The memory 1062 may be any electronic component capable of storing electronic information. The memory 1062 may be random access memory (RAM), read-only memory (ROM), magnetic disk storage media, optical storage media, flash memory devices in RAM, on-board memory included with the processor 1060, programmable read-only memory (PROM), erasable programmable read-only memory (EPROM), electrically erasable PROM (EEPROM), registers, and so forth, including combinations thereof.

Data 1064a and instructions 1066a may be stored in the memory 1062. The instructions 1066a may include one or more programs, routines, sub-routines, functions, procedures, etc. The instructions 1066a may include a single computer-readable statement or many computer-readable statements. The instructions 1066a may be executable by the processor 1060 to implement one or more of the methods or functions described herein. Executing the instructions 1066a may involve the use of the data 1064a that is stored in the memory 1062. FIG. 10 shows some instructions 1066b and data 1064b being loaded into the processor 1060 (which may originate from instructions 1066a and data 1064a).

The electronic device 1058 may also include one or more communication interfaces 1068 for communicating with other devices. The communication interface 1068 may be based on wired communication technology, wireless communication technology, or both. Examples of different types of communication interfaces 1068 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, and so forth.

The electronic device 1058 may also include one or more input devices 1070 and one or more output devices 1074. Examples of different kinds of input devices 1070 include a keyboard, mouse, microphone, remote control device, button, joystick, trackball, touchpad, lightpen, etc. For instance, the electronic device 1058 may include one or more microphones 1072 for capturing acoustic signals. In one configuration, a microphone 1072 may be a transducer that converts acoustic signals (e.g., voice, speech, noise, etc.) into electrical or electronic signals. Examples of different kinds of output devices 1074 include a speaker, printer, etc. For instance, the electronic device 1058 may include one or more speakers 1076. In one configuration, a speaker 1076 may be a transducer that converts electrical or electronic signals into acoustic signals.

One specific type of output device 1074 which may be included in an electronic device 1058 is a display device 1078. Display devices 1078 used with configurations disclosed herein may utilize any suitable image projection technology, such as a cathode ray tube (CRT), liquid crystal display (LCD), light-emitting diode (LED), gas plasma, electroluminescence, or the like. A display controller 1080 may also be provided, for converting data 1064a stored in the memory 1062 into text, graphics, and/or moving images (as appropriate) shown on the display device 1078.

The various components of the electronic device 1058 may be coupled together by one or more buses, which may include a power bus, a control signal bus, a status signal bus, a data bus, etc. For simplicity, the various buses are illustrated in FIG. 10 as a bus system 1082. It should be noted that FIG. 10 illustrates only one possible configuration of an electronic device 1058. Various other architectures and components may be utilized.

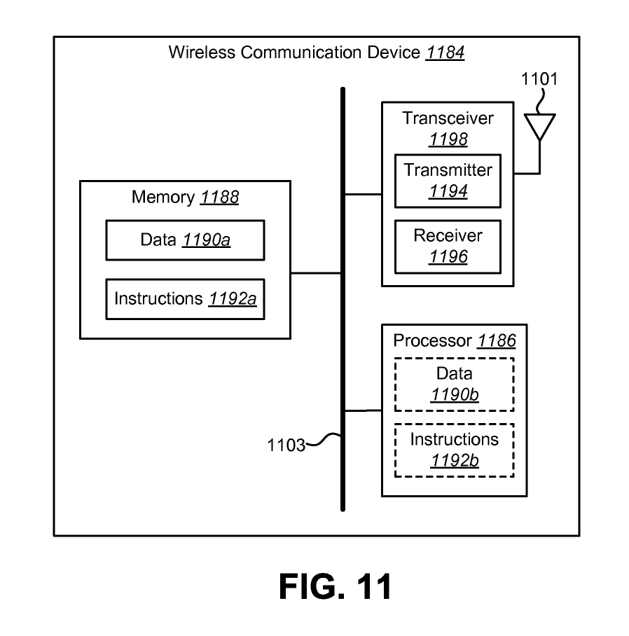

FIG. 11 illustrates certain components that may be included within a wireless communication device 1184. In some configurations, one or more of the low-pass filter circuits 102, 202, 502, 602, 702 and/or other circuitries or elements described herein may be implemented in accordance with the wireless communication device 1184 illustrated in FIG. 11.

The wireless communication device 1184 includes a processor 1186. The processor 1186 may be a general purpose single- or multi-chip microprocessor (e.g., an ARM), a special purpose microprocessor (e.g., a digital signal processor (DSP)), a microcontroller, a programmable gate array, etc. The processor 1186 may be referred to as a central processing unit (CPU). Although just a single processor 1186 is shown in the wireless communication device 1184 of FIG. 11, in an alternative configuration, a combination of processors 1186 (e.g., an ARM and DSP) could be used.

The wireless communication device 1184 also includes memory 1188 in electronic communication with the processor 1186 (e.g., the processor 1186 can read information from and/or write information to the memory 1188). The memory 1188 may be any electronic component capable of storing electronic information. The memory 1188 may be random access memory (RAM), read-only memory (ROM), magnetic disk storage media, optical storage media, flash memory devices in RAM, on-board memory included with the processor 1186, programmable read-only memory (PROM), erasable programmable read-only memory (EPROM), electrically erasable PROM (EEPROM), registers, and so forth, including combinations thereof.

Data 1190a and instructions 1192a may be stored in the memory 1188. The instructions 1192a may include one or more programs, routines, sub-routines, functions, procedures, code, etc. The instructions 1192a may include a single computer-readable statement or many computer-readable statements. The instructions 1192a may be executable by the processor 1186 to implement one or more of the methods or functions described herein. Executing the instructions 1192a may involve the use of the data 1190a that is stored in the memory 1188. FIG. 11 shows some instructions 1192b and data 1190b being loaded into the processor 1186 (which may come from instructions 1192a and data 1190a in memory 1188).

The wireless communication device 1184 may also include a transmitter 1194 and a receiver 1196 to allow transmission and reception of signals between the wireless communication device 1184 and a remote location (e.g., another wireless communication device, wireless communication device, etc.). The transmitter 1194 and receiver 1196 may be collectively referred to as a transceiver 1198. An antenna 1101 may be electrically coupled to the transceiver 1198. The wireless communication device 1184 may also include (not shown) multiple transmitters 1194, multiple receivers 1196, multiple transceivers 1198 and/or multiple antenna 1101.

The various components of the wireless communication device 1184 may be coupled together by one or more buses, which may include a power bus, a control signal bus, a status signal bus, a data bus, etc. For simplicity, the various buses are illustrated in FIG. 11 as a bus system 1103.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “couple” and any variations thereof may indicate a direct or indirect connection between elements. For example, a first element coupled to a second element may be directly connected to the second element, or indirectly connected to the second element through another element.

It should be noted that one or more of the features, functions, procedures, components, elements, structures, etc., described in connection with any one of the configurations described herein may be combined with one or more of the functions, procedures, components, elements, structures, etc., described in connection with any of the other configurations described herein, where compatible. In other words, any compatible combination of the functions, procedures, components, elements, etc., described herein may be implemented in accordance with the systems and methods disclosed herein.

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A low-pass filter circuit, comprising:
a pseudo-resistor comprising at least one metal-oxide-semiconductor field-effect transistor that receives a digital power supply domain signal; and
a capacitor coupled to the pseudo-resistor, wherein the capacitor provides a filtered signal,
wherein the pseudo-resistor comprises a p-channel metal-oxide-semiconductor field-effect transistor and an n-channel metal-oxide-semiconductor field-effect transistor, wherein a source of the p-channel metal-oxide-semiconductor field-effect transistor is coupled to a source of the n-channel metal-oxide-semiconductor field-effect transistor, a drain of the p-channel metal-oxide-semiconductor field-effect transistor is coupled to a drain of the n-channel metal-oxide-semiconductor field-effect transistor, a gate of the p-channel metal-oxide-semiconductor field-effect transistor is coupled the drain of the p-channel metal-oxide-semiconductor field-effect transistor, and a gate of the n-channel metal-oxide-semiconductor field-effect transistor is coupled to the drain of the n-channel metal-oxide-semiconductor field-effect transistor.

2. The low-pass filter circuit of claim 1, wherein the at least one metal-oxide-semiconductor field-effect transistor is at least one of a group consisting of an re-channel metal-oxide-semiconductor field-effect transistor and a p-channel metal-oxide-semiconductor field-effect transistor.

3. The low-pass filter circuit of claim 1, wherein the low-pass filter circuit attenuates noise in the digital power supply domain signal to provide the filtered signal.

4. The low-pass filter circuit of claim 1, wherein the pseudo-resistor is coupled to a first circuitry in a digital power supply domain.

5. The low-pass filter circuit of claim 4, wherein the first circuitry comprises a digital inverter that receives a digital input signal and provides the digital power supply domain signal, wherein the first circuitry is coupled to a digital power supply that provides power to the first circuitry.

6. The low-pass filter circuit of claim 1, wherein the pseudo-resistor and the capacitor are coupled to a second circuitry.

7. The low-pass filter circuit of claim 6, wherein the second circuitry comprises an inverter that receives the filtered signal and provides an analog power supply domain signal, wherein the second circuitry is coupled to an analog power supply that provides power to the inverter.

8. The low-pass filter circuit of claim 1, wherein the low-pass filter circuit is a first order low-pass filter.

9. The low-pass filter circuit of claim 1, wherein the pseudo-resistor provides low resistance when the digital power supply domain signal is in transition, and wherein the pseudo-resistor provides high resistance when the digital power supply domain signal is not in transition.

10. The low-pass filter circuit of claim 1, wherein the at least one metal-oxide-semiconductor field-effect transistor has its transistor body coupled to its transistor source.

11. (canceled)

12. The low-pass filter circuit of claim 1, wherein the source of the p-channel metal-oxide-semiconductor field-effect transistor receives the digital power supply domain signal and the drain of the p-channel metal-oxide-semiconductor field-effect transistor is coupled to the capacitor.

13. The low-pass filter circuit of claim 1, wherein the source of the n-channel metal-oxide-semiconductor field-effect transistor receives the digital power supply domain signal and the drain of the n-channel metal-oxide-semiconductor field-effect transistor is coupled to the capacitor.

14. A method for providing low-pass filtering, comprising:
receiving a digital power supply domain signal by a pseudo-resistor, wherein the pseudo-resistor comprises at least one metal-oxide-semiconductor field-effect transistor; and
providing the digital power supply domain signal to a capacitor coupled to the pseudo-resistor to produce a filtered signal,
wherein the pseudo-resistor comprises a p-channel metal-oxide-semiconductor field-effect transistor and an n-channel metal-oxide-semiconductor field-effect transistor, wherein a source of the p-channel metal-oxide-semiconductor field-effect transistor is coupled to a source of the n-channel metal-oxide-semiconductor field-effect transistor, a drain of the p-channel metal-oxide-semiconductor field-effect transistor is coupled to a drain of the n-channel metal-oxide-semiconductor field-effect transistor, a gate of the p-channel metal-oxide-semiconductor field-effect transistor is coupled the drain of the p-channel metal-oxide-semiconductor field-effect transistor, and a gate of the n-channel metal-oxide-semiconductor field-effect transistor is coupled to the drain of the n-channel metal-oxide-semiconductor field-effect transistor.

15. The method of claim 14, wherein the at least one metal-oxide-semiconductor field-effect transistor is at least one of a group consisting of an n-channel metal-oxide-semiconductor field-effect transistor and a p-channel metal-oxide-semiconductor field-effect transistor.

16. The method of claim 14, wherein the pseudo-resistor is coupled to a first circuitry in a digital power supply domain.

17. The method of claim 16, further comprising:
receiving, by the first circuitry, a digital input signal;
providing, by the first circuitry, a digital power supply domain signal; and
providing, by a digital power supply, power to the first circuitry, wherein the first circuitry is coupled to the digital power supply.

18. The method of claim 14, wherein the pseudo-resistor and the capacitor are coupled to a second circuitry.

19. The method of claim 18, further comprising:
receiving, by the second circuitry, the filtered signal;
providing, by the second circuitry, an analog power supply domain signal; and
providing, by an analog power supply, power to the second circuitry, wherein the second circuitry is coupled to the analog power supply.

20. The method of claim 14, further comprising:
providing, by the pseudo-resistor, low resistance when the digital power supply domain signal is in transition; and
providing, by the pseudo-resistor, high resistance when the digital power supply domain signal is not in transition.

21. The method of claim 14, wherein the at least one metal-oxide-semiconductor field-effect has its transistor body coupled to its transistor source.

22. (canceled)

23. The method of claim 14, wherein the source of the p-channel metal-oxide-semiconductor field-effect transistor receives the digital power supply domain signal and flail the drain of the p-channel metal-oxide-semiconductor field-effect transistor is coupled to the capacitor.

24. The method of claim 14, wherein the source of the n-channel metal-oxide-semiconductor field-effect transistor receives the digital power supply domain signal and the drain of the n-channel metal-oxide-semiconductor field-effect transistor is coupled to the capacitor.

25. A computer-program product for providing low-pass filtering, comprising a non-transitory tangible computer-readable medium having instructions thereon, the instructions comprising:
program code (“code”) for causing a pseudo-resistor to receive a digital power supply domain signal, wherein the pseudo-resistor comprises at least one metal-oxide-semiconductor field-effect transistor; and
code for causing a capacitor coupled to the pseudo-resistor to receive the digital power supply domain signal to generate a filtered signal,
wherein the pseudo-resistor comprises a p-channel metal-oxide-semiconductor field-effect transistor and an n-channel metal-oxide-semiconductor field-effect transistor, wherein a source of the p-channel metal-oxide-semiconductor field-effect transistor is coupled to a source of the n-channel metal-oxide-semiconductor field-effect transistor, a drain of the p-channel metal-oxide-semiconductor field-effect transistor is coupled to a drain of the n-channel metal-oxide-semiconductor field-effect transistor, a gate of the p-channel metal-oxide-semiconductor field-effect transistor is coupled the drain of the p-channel metal-oxide-semiconductor field-effect transistor, and a gate of the n-channel metal-oxide-semiconductor field-effect transistor is coupled to the drain of the n-channel metal-oxide-semiconductor field-effect transistor.

26. The computer-program product of claim 25, wherein the at least one metal-oxide-semiconductor field-effect transistor is at least one of a group consisting of an n-channel metal-oxide-semiconductor field-effect transistor and a p-channel metal-oxide-semiconductor field-effect transistor.

27. The computer-program product of claim 25, wherein the pseudo-resistor is coupled to a first circuitry in a digital power supply domain.

28. The computer-program product of claim 27, wherein the instructions further comprise:
code for causing the first circuitry to receive a digital input signal;
code for causing the first circuitry to provide a digital power supply domain signal; and
code for causing a digital power supply to provide power to the first circuitry, wherein the first circuitry is coupled to the digital power supply.

29. The computer-program product of claim 27, wherein the first circuitry comprises an inverter.

30. The computer-program product of claim 25, wherein the pseudo-resistor and the capacitor are coupled to a second circuitry.

31. The computer-program product of claim 30, wherein the instructions further comprise:
code for causing the second circuitry to receive the filtered signal;
code for causing the second circuitry to provide an analog power supply domain signal; and
code for causing an analog power supply to provide power to the second circuitry, wherein the second circuitry is coupled to the analog power supply.

32. The computer-program product of claim 30, wherein the second circuitry comprises an inverter.

33. The computer-program product of claim 25, wherein the instructions further comprise:
code for causing the pseudo-resistor to provide low resistance when the digital power supply domain signal is in transition; and
code for causing the pseudo-resistor to provide high resistance when the digital power supply domain signal is not in transition.

34. The computer-program product of claim 25, wherein the at least one metal-oxide-semiconductor field-effect transistor has its transistor body coupled to its transistor source.

35. An apparatus for providing low-pass filtering, comprising:
means for providing a resistance that receives a digital power supply domain signal, wherein the means for providing the resistance does not include a passive element; and
means for providing a capacitance, wherein the means for providing the capacitance is coupled to the means for providing the resistance, and wherein the means for providing the capacitance provides a filtered signal,
wherein the means for providing a resistance comprises a p-channel metal-oxide-semiconductor field-effect transistor and an n-channel metal-oxide-semiconductor field-effect transistor, wherein a source of the p-channel metal-oxide-semiconductor field-effect transistor is coupled to a source of the n-channel metal-oxide-semiconductor field-effect transistor, a drain of the p-channel metal-oxide-semiconductor field-effect transistor is coupled to a drain of the re-channel metal-oxide-semiconductor field-effect transistor, a gate of the p-channel metal-oxide-semiconductor field-effect transistor is coupled the drain of the p-channel metal-oxide-semiconductor field-effect transistor, and a gate of the n-channel metal-oxide-semiconductor field-effect transistor is coupled to the drain of the n-channel metal-oxide-semiconductor field-effect transistor.

36. The apparatus of claim 35, wherein the means for providing a resistance comprises at least one of a group consisting of an n-channel metal-oxide-semiconductor field-effect transistor and a p-channel metal-oxide-semiconductor field-effect transistor.

37. The apparatus of claim 35, wherein the means for receiving a digital power supply domain signal is coupled to means for providing a digital power supply domain signal in a digital power supply domain.

38. The apparatus of claim 35, wherein the means for providing a resistance is coupled to means for providing a digital power supply domain signal, wherein the means for providing a digital power supply domain signal is coupled to means for providing power, and wherein the means for providing the digital power supply domain signal receives a digital input signal.

39. The apparatus of claim 35, wherein the means for receiving a digital power supply domain signal is coupled to means for providing an analog power supply domain signal.

40. The apparatus of claim 35, wherein the means for providing a resistance is coupled to means for providing an analog power supply domain signal, wherein the means for providing an analog power supply domain signal is coupled to means for providing power, and wherein the means for providing the analog power supply domain signal receives the filtered signal.

41. The apparatus of claim 35, wherein the means for providing a resistance provides a low resistance when the digital power supply domain signal is in transition and provides a high resistance when the digital power supply domain signal is not in transition.

42. The apparatus of claim 35, wherein the source of the p-channel metal-oxide-semiconductor field-effect transistor receives the digital power supply domain signal and the drain of the p-channel metal-oxide-semiconductor field-effect transistor is coupled to the means for providing a capacitance.

43. The apparatus of claim 35, wherein the source of the n-channel metal-oxide-semiconductor field-effect transistor receives the digital power supply domain signal and the drain of the n-channel metal-oxide-semiconductor field-effect transistor is coupled to the means for providing a capacitance.
